(19) United States
(12) Patent Application Publication
(10) Pub. No.: US 2026/0096297 A1
(43) Pub. Date: Apr. 2, 2026

(54) DISPLAY PANEL AND METHOD OF MANUFACTURING DISPLAY PANEL

(71) Applicant: HKC CORPORATION LIMITED, SHENZHEN (CN)

(72) Inventors: Jiansheng MA, SHENZHEN (CN); Chuan WU, SHENZHEN (CN); Zhonglin CAO, SHENZHEN (CN); Lidan YE, SHENZHEN (CN)

(73) Assignee: HKC CORPORATION LIMITED, SHENZHEN (CN)

(21) Appl. No.: 19/334,608

(22) Filed: Sep. 19, 2025

(30) Foreign Application Priority Data
Sep. 30, 2024 (CN) 202411393325.0

(51) Int. Cl. H10K 59/122; H10K 59/12; H10K 59/131; H10K 59/80

(52) U.S. Cl. CPC H10K 59/122; H10K 59/1201; H10K 59/131; H10K 59/80515

(57) ABSTRACT

A display panel includes: a first light emitting substrate and a second light emitting substrate stacked with the first light emitting substrate. The first light emitting substrate includes: a first substrate defining first through holes; and first light emitting units, arranged on a surface of the first substrate. A first conductive portion is received in each first through hole. The second light emitting substrate includes: a second substrate and second light emitting units, arranged on a surface of the second substrate. A second anode electrode of the second light emitting substrate includes a second anode conductive layer received in a second opening of a second pixel definition layer and a second anode extension portion extending from the second anode conductive layer to the second pixel definition. The first conductive portion is electrically connected to the second anode extension portion.

### CROSS REFERENCE TO RELATED APPLICATIONS

The present application claims the priority of the Chinese patent application No. 202411393325.0, filed on September 30, 2024, contents of which are incorporated herein by its entireties.

### TECHNICAL FIELD

Embodiments of the present disclosure relate to the technical field of displaying, and more specifically, to a display panel and a method of manufacturing a display panel.

### BACKGROUND

In the organic light emitting diode (OLED) display technology, tandem OLED technology are developed to improve display brightness. The tandem OLEDs have high brightness, a long service life, lower power consumption and lower weight, and therefore, the tandem OLEDs may be ideal for portable devices. However, in the related art, during manufacturing the tandem OLEDs, as the number of layers of OLEDs being stacked, a produce yield may be reduced, and corresponding manufacturing costs may be increased dramatically.

### SUMMARY

The present disclosure provides a display panel and a method of manufacturing a display panel to solve the technical problem of the tandem OLEDs having the low produce yield and increased corresponding manufacturing costs.

In a first aspect, the present disclosure provides a display panel, including: a first light emitting substrate and a second light emitting substrate stacked with the first light emitting substrate. The first light emitting substrate includes: a first substrate, having a first surface, a second surface opposite to the first surface, and a plurality of first through holes extending from the first surface to the second surface, where a first conductive portion is received in each of the plurality of first through holes; a plurality of first light emitting units, arranged on a side of the first surface of the first substrate, where each of the plurality of first light emitting units includes a first anode electrode, a first pixel definition layer, a first organic light emitting layer and a first cathode electrode. The second light emitting substrate includes: a second substrate, having a third surface and a fourth surface opposite to the third surface; a plurality of second light emitting units, arranged on a side of the third surface of the second substrate, where each of plurality of second light emitting units includes a second anode electrode, a second pixel definition layer, a second organic light emitting layer, and a second cathode electrode; the second pixel definition layer defines a second opening. The second anode electrode includes a second anode conductive layer received in the second opening and a second anode extension portion extending from a side of the second anode conductive layer to a surface of the second pixel definition layer away from the second substrate; and an end of the first conductive portion away from the plurality of first light emitting units is electrically connected to the second anode extension portion. The first light emitting substrate further includes a drive circuit layer, the drive circuit layer includes a drive circuit; the first anode electrode is electrically connected to the drive circuit; the other end of the first conductive portion is electrically connected to the drive circuit or the first anode electrode; and/or the second light emitting substrate further includes a drive circuit layer, the drive circuit layer includes a drive circuit, the drive circuit is electrically connected to the second anode electrode.

In a second aspect, the present disclosure provides a method of manufacturing a display panel, including:

providing a first light emitting substrate; where the first light emitting substrate includes: a first substrate, having a first surface, a second surface opposite to the first surface, and a plurality of first through holes extending from the first surface to the second surface, where a first conductive portion is received in each of the plurality of first through holes; and a plurality of first light emitting units, arranged on a side of the first surface of the first substrate, where each of the plurality of first light emitting units includes a first anode electrode, a first pixel definition layer, a first organic light emitting layer and a first cathode electrode;

providing a second light emitting substrate; where the second light emitting substrate includes: a second substrate, having a third surface and a fourth surface opposite to the third surface; a plurality of second light emitting units, arranged on a side of the third surface of the second substrate; where each of the plurality of second light emitting units includes a second anode electrode, a second pixel definition layer, a second organic light emitting layer, and a second cathode electrode; the second pixel definition layer has a second opening; where the second anode electrode includes a second anode conductive layer received in the second opening and a second anode extension portion extending from a side of the second anode conductive layer to a surface of the second pixel definition layer away from the second substrate; and

stacking the second light emitting substrate and the first light emitting substrate, enabling one end of the first conductive portion away from the first light emitting unit to be electrically connected to the second anode extension portion.

### BRIEF DESCRIPTION OF THE DRAWINGS

In order to more clearly illustrate technical solutions in embodiments of the present disclosure, the accompanying drawings for describing the embodiments will be briefly introduced in the following. Apparently, the following described drawings are only some of the embodiments of the present disclosure, any ordinary skilled person in the art may obtain drawings based on the following drawings without any creative work.

FIG. 1 is a side plane view of a display panel according to an embodiment of the present disclosure.

FIG. 2 is a side plane view of the display panel according to a first embodiment of the present disclosure.

FIG. 3 is a side plane view of the display panel according to a second embodiment of the present disclosure.

FIG. 4 is a side plane view of the display panel according to a third embodiment of the present disclosure.

FIG. 5 is another side plane view of the display panel according to an embodiment of the present disclosure, where a first hole section and a second hole section of the first through hole are communicated to each other.

FIG. 6 is an enlarged view of a portion A shown in FIG. 1.

FIG. 7 is a flow chart of a method of manufacturing the display panel according to an embodiment of the present disclosure.

Reference numerals in the drawings:

100, display panel; 1, first light emitting substrate; 2, second light emitting substrate; 10, first substrate; 101, first surface; 102, second surface; 103, first through hole; 104, first conductive portion; 1041, first hole section; 1042, second hole section; 11, first light emitting unit; 111, first anode electrode; 1111, first anode conductive layer; 1112, first anode extension portion; 112, first pixel definition layer; 1121, first opening; 113, first organic light emitting layer; 114, first cathode electrode; 115, second through hole; 116, second conductive portion; 12, first drive circuit layer; 121, first drive circuit; 13, conductive interconnection layer; 14, first connection portion; 20, second substrate; 201, third surface; 202, fourth surface; 21, second light emitting unit; 211, second anode electrode; 2111, second anode conductive layer; 2112, second anode extension portion; 212, second pixel definition layer; 2121, second opening; 213, second organic light emitting layer; 214, second cathode electrode; 215, insulating layer; 22, second drive circuit layer; 221, second drive circuit; 23, connection; 24, via-hole conduction portion; 25, second connection portion; 30, frame adhesive or bonding layer; and 40, encapsulation layer.

### DETAILED DESCRIPTIONS

The technical solutions in the embodiments of the present disclosure will be clearly and completely described below by referring to the accompanying drawings in the embodiments of the present disclosure. Apparently, the described embodiments are only a part of, not all of, the embodiments of the present disclosure. All other embodiments, which are obtained by any ordinary skilled person in the art based on the embodiments in the present disclosure without making creative work, shall fall within the scope of the present disclosure.

Terms “first”, “second”, and “third” in the present disclosure are used for descriptive purposes only and are not to indicate or imply relative importance or implicitly specifying the number of technical features. Therefore, a feature defined with “first”, “second”, “third” may include at least one such feature, either explicitly or implicitly. In the description of the present disclosure, “a plurality of” means at least two, such as two, three, and so on, unless otherwise expressly and specifically limited. All directional indications (such as up, down, left, right, front, rear ......) in the embodiments of the present disclosure are only used to explain a relative positional relationship and movement between components at a particular attitude (the attitude as shown in the accompanying drawings). The directional indication may be changed accordingly when the particular attitude is changed. Furthermore, terms “include” and “have” and any variations thereof are intended to cover non-exclusive inclusion. For example, a process, a method, a system, a product or an apparatus including a series of steps or units is not limited to the listed steps or units, but may further include steps or units that are not listed or steps or units that are inherently included in the process, the method, the system, the product or the apparatus.

Reference to “embodiments” herein means that particular features, structures, or characteristics described in an embodiment may be included in at least one embodiment of the present disclosure. The phrase at various sections in the specification does not necessarily refer to one same embodiment, nor separate or alternative embodiments that are mutually exclusive of other embodiments. Any ordinary skilled person in the art shall understand that, both explicitly and implicitly, the embodiments described herein may be combined with other embodiments.

During research, it is found that, compared to a liquid crystal display (LCD), an organic light emitting diode (OLED) display panel may be in an all-solid-state, may actively emit light, may have high brightness and high contrast, may be ultra-thin, may have low power consumption and no limitation in viewing angles, and may have a wide operating temperature range. Therefore, the OLED display panel has been increasingly emphasized. However, due to the OLED display panel having high manufacturing costs and may be prepared based on a complex process, any ordinary skilled person have been constantly looking for improvements.

In the OLED display technology, tandem OLED technology are developed to improve display brightness. A tandem OLED display may be an innovative display panel, which is made by stacking at least two layers of OLED panels. Compared to traditional OLED panels, the tandem OLED display may have significant improvements in various aspects. The tandem OLEDs may have high brightness, a long service life, lower power consumption and lower weight. Therefore, the tandem OLEDs may be ideal for portable mobile devices. For the tandem OLEDs, light emitting layers may be stacked, drive elements and power supply circuits may be simplified, such that reliance on optical components may be reduced. The above advantages of the tandem OLEDs enable the tandem OLEDs to be an important component to enhance a displaying effect of mobile device.

However, in practice, during manufacturing the tandem OLEDs, as the number of layers of OLEDs being stacked increases, the product yield may be reduced. Therefore, corresponding manufacturing costs may be increased significantly.

In the related art, an organic functional layer (light emitting layer) of the tandem OLED display panel may be prepared by using a fine metal mask (FMM) or an open mask. The open mask may be low costly and may be prepared based on a simpler process, compared to the fine metal mask.

In order to solve the above problems, the present disclosure provides an innovative tandem OLED display panel and a method of manufacturing the tandem OLED display panel, so as to significantly improve the yield of OLED products and to simplify the entire manufacturing processes, such that a manufacturing efficiency and product quality may be improved.

As shown in FIGS. 1 and 6, FIG. 1 is a side plane view of a display panel 100 according to an embodiment of the present disclosure; and FIG. 6 is an enlarged view of a portion A shown in FIG. 1.

The display panel 100 may include a first light emitting substrate 1 and a second light emitting substrate 2. The first light emitting substrate 1 and the second light emitting substrate 2 are stacked on each other. For example, the second light emitting substrate 2 and the first light emitting substrate 1 may be secured by adhesives or bonding.

In the present embodiment, the first light emitting substrate 1 may include a first substrate 10 and a plurality of first light emitting units 11. The first substrate 10 may have a first surface 101, a second surface 102 opposite to the first surface 101, and a plurality of first through holes 103 extending from the first surface 101 to the second surface 102. A first conductive portion 104 may be received in each of the plurality of first through holes 103. The first through hole 103 may be understood as a hole that penetrates the substrate from the first surface 101 to the second surface 102. The first conductive portion 104 may be formed by filling or plating a conductive material within the first through hole 103, for example, the conductive material may be a metal or metal oxide, and the like, which is not limited herein. The plurality of first light emitting units 11 may be arranged on a side of the first surface 101 of the first substrate 10. Each of the plurality of first light emitting units 11 may include a first anode electrode 111, a first pixel definition layer 112, a first organic light emitting layer 113, and a first cathode electrode 114. The first pixel definition layer 112 is configured to define a boundary of the first organic light emitting layer 113 of each first light emitting unit, preventing an organic material, when being deposited, from spreading to other pixel regions. First organic light emitting layers 113 of the plurality of first light emitting units 11 may include three light emitting materials, which are a red light emitting material (R), a green light emitting material (G), and a blue light emitting material (B). First cathode electrodes 114 of the plurality of first light emitting units 11 may be connected to each other to form one integral structure. The first anode electrode 111, the first organic light emitting layer 113, and the first cathode electrode 114 may be stacked sequentially. A plurality of first anode electrodes 111 of the plurality of first light emitting units 11 may be spaced apart from each other by the first pixel definition layer 112. The first pixel definition layer 112 may have a first opening 1121 to expose the first anode electrode 111. In the present embodiment, the first substrate 10 may be a glass substrate; the first anode electrode 111 may be a light-transmissive conductive layer, for example, the first anode electrode 111 may be made of a material such as indium tin oxide (ITO) or indium zinc oxide (IZO). In this way, the first anode electrode 111 may have an ideal electrical conductivity and light-transmissive performance.

In the present disclosure, through glass vias (TGVs) may be finely defined in the glass substrate, such that a conductive interface of the anode electrode at a rear side of a glass element may be formed. The above innovative technology significantly improves conductivity performance of the glass element.

In the present embodiment, the second light emitting substrate 2 may include a second substrate 20 and a plurality of second light emitting units 21. The second substrate 20 may have a third surface 201 and a fourth surface 202 opposite to the third surface 201. The plurality of second light emitting units 21 are arranged on a side of the third surface 201 of the second substrate 20. Each of the plurality of second light emitting units 21 may include a second anode electrode 211, a second pixel definition layer 212, a second organic light emitting layer 213, and a second cathode electrode 214. The second pixel definition layer 212 has a second opening 2121. The second pixel definition layer 212 may be configured to define a boundary of the second organic light emitting layer 213 of each second light emitting unit 21, preventing an organic material, during being deposited, from spreading to other pixel regions. Second organic light emitting layers 213 of the plurality of second light emitting units 21 may include three light emitting materials, which are a red light emitting material (R), a green light emitting material (G), and a blue light emitting material (B). Second cathode electrodes 214 of the plurality of second light emitting units 21 may be connected to each other to form one integral structure. The second anode electrode 211, the second organic light emitting layer 213, and the second cathode electrode 214 may be stacked sequentially. A plurality of second anode electrodes 211 of the plurality of second light emitting units 21 may be spaced apart from each other by the second pixel definition layer 212, and each second anode electrode 211 may be exposed through the second opening 2121. In the present embodiment, the second substrate 20 may be a glass substrate or a plastic substrate, or the like. The second anode electrode 211 may be a light-transmissive conductive layer, for example, the second anode electrode 211 may be made of indium tin oxide (ITO) or indium zinc oxide (IZO), or the like, such that the second anode electrode 211 may have ideal conductivity and light-transmissive performance.

Each of the plurality of second light emitting units 21 may further have an insulating layer 215. The insulating layer 215 is disposed on a side of the second pixel definition layer 212 and the second organic light emitting layer 213 away from the second substrate 20 and may cover the second anode electrode 211, the second pixel definition layer 212, and a portion of the second organic light emitting layer 213. In this way, the second cathode electrode 214 and the second anode electrode 211 are prevented from contacting each other, such that a short circuit is prevented.

Specifically, the second anode electrode 211 may include a second anode conductive layer 2111 received in the second opening 2121 and a second anode extension portion 2112. The second anode extension portion 2112 may extend from a side of the second anode conductive layer 2111 to reach a surface of the second pixel definition layer 212 away from the second substrate 20. An end of the first conductive portion 104 away from the first light emitting unit 11 may be electrically connected to the second anode extension portion 2112, and the other end of the first conductive portion 104 may be electrically connected to the first anode electrode 111.

In the present embodiment, at least one of the first light emitting substrate 1 and the second light emitting substrate 2 may further include a drive circuit layer (not labeled in the drawings).

In an embodiment, for example, the first light emitting substrate 1 may include a first drive circuit layer 12, and the first drive circuit layer 12 may include a first drive circuit 121 that may be electrically connected to the first anode electrode 111. An end of the first conductive portion 104 away from the first light emitting units 11 may be electrically connected to the second anode extension portion 2112, and the other end of the first conductive portion 104 may be electrically connected to the first drive circuit 121 or to the first anode electrode 111.

In another embodiment, for example, the second light emitting substrate 2 may include a second drive circuit layer 22, and the second drive circuit layer 22 may include a second drive circuit 221 electrically connected to the second anode electrode 211.

It can be understood that when the first light emitting substrate 1 and the second light emitting substrate 2 are stacked. The first drive circuit layer 12 may be arranged only in the first light emitting substrate 1, and the second drive circuit layer 22 may be omitted from the second light emitting substrate 2. The first drive circuit layer 12 arranged in the first light emitting substrate 1 may control electrical components arranged both on the first light emitting substrate 1 and on the second light emitting substrate 2. In this way, manufacturing costs may significantly be saved. Furthermore, since no other light emitting substrates may be arranged on a surface of the first light emitting substrate 1 away from the second substrate, arranging the first drive circuit layer 12 in the first light emitting substrate 1 may facilitate a flexible printed circuit board (FPC) to be bound.

A connection 23 at which the first conductive portion 104 and the second anode extension 2112 are electrically connected to each other may be further secured by bonding or soldering. Meanwhile, a frame adhesive or a bonding layer 30, such as an annular bonding layer, may be arranged between the second surface 102 of the first substrate 10 and the third surface 201 of the second substrate 20. In this way, sealing between the first light emitting substrate 1 and the second light emitting substrate 2 may be formed, and the first light emitting substrate 1 and the second light emitting substrate 2 may be stably connected to each other.

To be noted that the display panel 100 in the present disclosure is not limited to including only the first light emitting substrate 1 and the second light emitting substrate 2, the display panel 100 may further include a third light emitting substrate (not shown in the drawings), a fourth light emitting substrate (not shown in the drawings), and so on. In a plurality of light emitting substrates that are stacked with each other, at least one drive circuit layer may be arranged, and a topmost one light emitting substrate of the plurality of light emitting substrates may be arranged with the drive circuit layer, such that the flexible printed circuit board (not shown) may be bound to a surface of the topmost one light emitting substrate. In addition, in order to ensure light transmittance performance of the display panel 100, only a bottommost one light emitting substrate of the plurality of light emitting substrates may be a non-transparent substrate, the rest light emitting substrates may all be configured as light-transparent substrates, which may be glass substrates. It is understood that the plurality of stacked light emitting substrates may be prepared in a same structure, for example, the first light emitting substrate 1 and the second light emitting substrate 2 may be prepared in a same structure. Alternatively, the bottommost light emitting substrate may be configured the same as the second light emitting substrate 2, and the rest light emitting substrates located above the bottommost light emitting substrate may be configured the same as the first light emitting substrate 1. Alternatively, one light emitting substrate at a certain layer of the plurality of stacked light emitting substrates may be omitted according to demands of a specific product. Alternatively, materials of one or more functional layers may be changed, so as to improve the display brightness, satisfy demands of a user, and save manufacturing costs. Specific configuration may be determined as needed, and will not be limited herein.

A specific structure of the display panel 100 may be described below by referring to specific embodiments.

### First Embodiment:

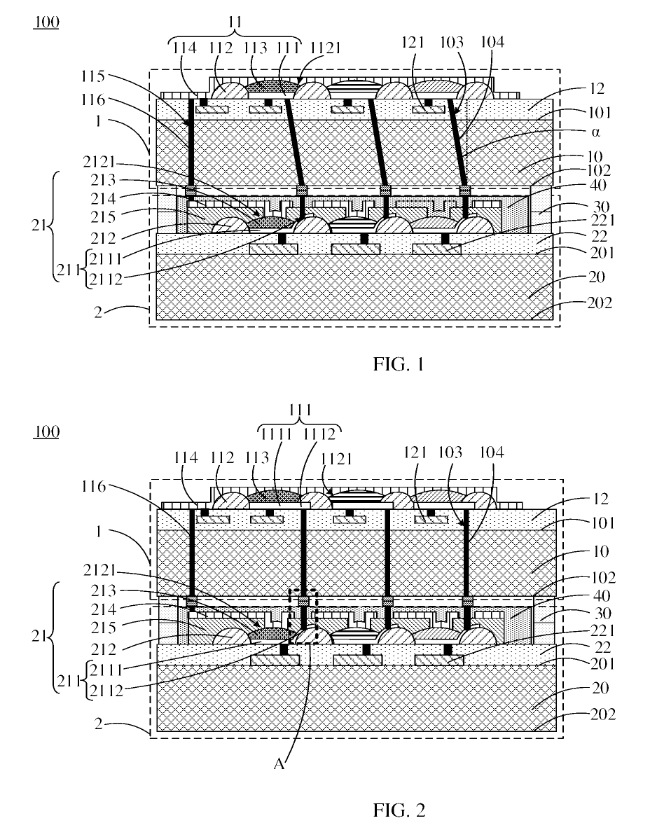

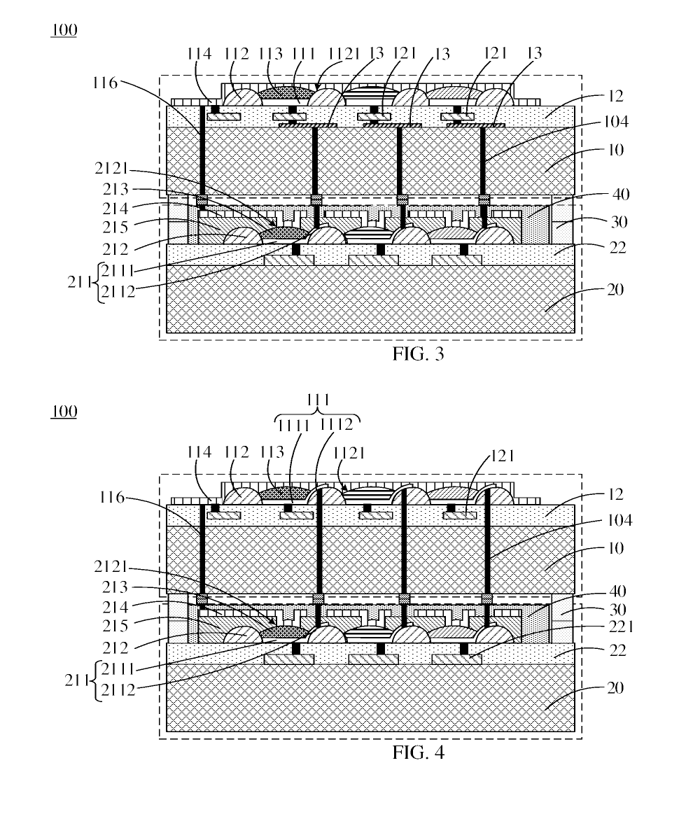

As shown in FIG. 2, FIG. 2 is a side plane view of the display panel according to the first embodiment of the present disclosure.

As shown in FIG. 2, the first anode electrode 111 may include a first anode conductive layer 1111 received in the first opening 1121 and the first anode extension portion 1112 extending from a side of the first anode conductive layer 1111 to a location between the first pixel definition layer 112 and the first substrate 10. An end of the first conductive portion 104 may be electrically connected to the second anode extension portion 2112, and the other end of the first conductive portion 104 may be electrically connected to the first anode extension portion 1112. It is understood that the first anode extension portion 1112 and the first anode conductive layer 1111 may be may be prepared by a same process, such that the preparation process may be simplified. Meanwhile, in order to enable the first anode extension portion 1112 to be disposed between the first pixel definition layer 112 and the first substrate 10, the first anode extension portion 1112 may be prepared firstly, and the first pixel definition layer 112 may be prepared subsequently. It is understood that the first anode extension portion 1112 of the first anode electrode 111 of one of the plurality of first light emitting units 11 may be spaced apart from the first anode conductive layer 1111 corresponding to the first organic light emitting layer 113 of another one of the plurality of first light emitting units 11 adjacent to the instant one of the plurality of first light emitting units 11. For example, one end of the first conductive portion 104 may be electrically connected to the first anode extension portion 1112 of the red organic light emitting layer of the first light emitting substrate 1, and the other end of the first conductive portion 104 may be electrically connected to the second anode extension portion 2112 of the red organic light emitting layer of the second light emitting substrate 2. In this case, the first anode extension portion 1112 of the red organic light emitting layer of the first light emitting substrate 1 may be spaced apart from the first anode conductive layer 1111 and the first anode extension portion 1112 of the green organic light emitting layer of the first light emitting substrate 1 adjacent to the red organic light emitting layer. In this way, a short circuit may be prevented.

### Second Embodiment:

As shown in FIG. 3, FIG. 3 is a side plane view of the display panel according to a second embodiment of the present disclosure.

As shown in FIG. 3, in the present embodiment, the first pixel definition layer 112 may define the first opening 1121, such that the first anode electrode 111 may be exposed through the first opening 1121. The first light emitting substrate 1 may include the first drive circuit layer 12, the first drive circuit layer 12 may include the first drive circuit 121. The first light emitting substrate 1 may further include a conductive interconnection layer 13. The conductive interconnection layer 13 may be disposed between the first substrate 10 and the first drive circuit layer 12 and may be electrically connected to the first drive circuit 121. For example, the conductive interconnection layer 13 may be formed by patterning a metal layer (not shown) arranged on the first substrate 10. The conductive interconnection layer 13 may be made from metal or metal oxide.

In the present embodiment, one end of the first conductive portion 104 may be electrically connected to the second anode extension portion 2112, and the other end of the first conductive portion 104 may be electrically connected to the conductive interconnection layer 13. Meanwhile, since the first drive circuit 121 is electrically connected to the first anode electrode 111, the above connection may enable the first light emitting substrate 1 and the second light emitting substrate 2 to be conduced with each other.

### Third Embodiment:

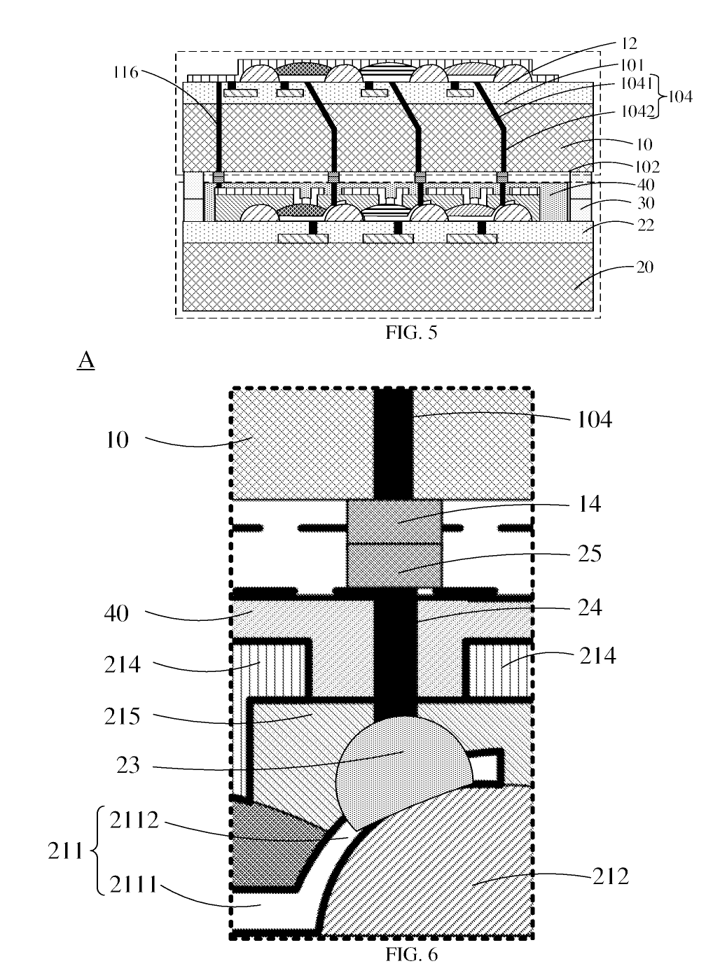

As shown in FIGS. 4 and 5, FIG. 4 is a side plane view of the display panel according to a third embodiment of the present disclosure; and FIG. 5 is another side plane view of the display panel according to an embodiment of the present disclosure, where a first hole section and a second hole section of the first through hole are communicated to each other.

As shown in FIG. 4, the first pixel definition layer 112 may define the first opening 1121, such that the first anode electrode 111 may be exposed through the first opening 1121. In the present embodiment, the first anode electrode 111 may include the first anode conductive layer 1111 received in the first opening 1121 and the first anode extension portion 1112. The first anode extension portion 1112 may extend from a side of the first anode conductive layer 1111 to the surface of the first pixel definition layer 112 away from the first substrate 10. That is, the first anode extension portion 1112 may cover a portion of the surface of the first pixel definition layer 112 away from the first substrate 10. In addition, the first anode extension portion 1112 of one of the plurality of first light emitting units 11 needs to be spaced apart from the first anode electrode 111 corresponding to the first organic light emitting layer 113 of another one of the plurality of first light emitting units adjacent to the instant one of the plurality of first light emitting units. It can be understood that first anode extension portions 1112 arranged on the first light emitting substrate 1 may extend in a same direction. In this way, the first anode extension portion 1112 of one of the plurality of first light emitting units 11 may be prevented from contacting or crossing with the first anode electrode 111 corresponding to the first organic light emitting layer 113 of another one of the plurality of first light emitting units adjacent to the instant one of the plurality of first light emitting units, such that a short circuit may be prevented. The first through hole 103 may further penetrate the first pixel definition layer 112, for example, when depositing the first pixel definition layer 112, a position where the first through hole 103 may penetrate the first pixel definition layer 112 may be reserved. Alternatively, after depositing the first pixel definition layer 112 is completed, a hole may be defined in the first pixel definition layer 112 at a position corresponding the first through hole 103 penetrating the first pixel definition layer 112, such that the hole may be communicated to the first through hole 103. One end of the first conductive portion 104 may be electrically connected to the second anode extension portion 2112, and the other end of the first conductive portion 104 may may pass through the first pixel definition layer 112 and may be electrically connected to the first anode extension portion 1112.

As shown in FIGS. 2 to 4, in the above-described first embodiment to the third embodiment, the first opening 1121 and the second opening 2121 may be coaxially arranged, so as to ensure a light emitting effect of the display panel 100 having the first light emitting substrate 1 and the second light emitting substrate 2 that are stacked. Furthermore, first anode electrodes 111 (or second anode extension portions 2112) of the first light emitting substrate 1 and second anode extension portions 2112 of the second light emitting substrate 2 may be electrically connected to each other correspondingly. The first through hole 103 may be misaligned with the first opening 1121, such that the first conductive portion 104 formed by the first through hole 103 may be prevented from obscuring the first organic light emitting layer 113 arranged in the first opening 1121, ensuring a light emitting effect of the first organic light emitting layer 113.

As shown in FIGS. 2 to 4, in any of the above embodiments, the first through hole 103 may be a straight through hole that is perpendicular to the first substrate 10. Alternatively, as shown in FIG. 1, the first through hole 103 may be a straight through hole that is inclined with respect to a thickness direction of the first substrate 10. For example, an angle α may be formed between an extension direction of the first through hole 103 and the thickness direction of the first substrate 10. The straight through hole may be formed by performing punching from only the first substrate 101 or from only the second surface 102. Alternatively, the straight through hole may be formed by performing punching from both the first substrate 101 and the second surface 102, and a hole formed from the first substrate 101 and a hole formed from the second substrate 102 may be communicated to each other inside the first substrate 10.

Alternatively, in another embodiment, as shown in FIG. 5, the first through hole 103 may include a first hole section 1041 and a second hole section 1042 that is communicated to the first hole section 1041. The first hole section 1041 may extend from the first surface 101 to an interior of the first substrate 10. The second hole section 1042 may extend from the second surface 102 to the interior of the first substrate 10. The first hole section 1041 and the second hole section 1042 may be communicated to each other at the interior of the first substrate 10. One of the first hole sections 1041 and the second hole sections 1042 may extend along the thickness direction of the first substrate 10, and the other one of the first hole sections 1041 and the second hole sections 1042 may extend inclinedly relative to the thickness direction of the first substrate 10. As shown in FIG. 5, for example, the first hole section 1041 may extend inclinedly relative to the thickness direction of the first substrate 10. The second hole sections 1042 may extend along the thickness direction of the first substrate 10. It is understood that the first hole section 1041 may be formed by punching a hole from the first surface 101 of the first substrate 10, and the second hole section 1042 may be formed by punching a hole from the second surface 102 of the first substrate 10. Since both the first surface 101 and the second surface 102 are punched at the same time, such that a preparation efficiency may be improved, efficient conduction connection between the first light emitting substrate 1 and the second light emitting substrate 2 may be achieved.

As shown in FIGS. 1 to 5, in other embodiments, the first substrate 10 may further define a plurality of second through holes 115 extending from the first surface 101 to the second surface 102. A second conductive portion 116 may be received in each of the plurality of second through holes 115. One end of the second conductive portion 116 may be electrically connected to the first cathode electrode 114, and the other end of the second conductive portion 116 may be electrically connected to the second cathode electrode 214. The second conductive portion 116 may be formed by filling or electroplating a conductive material in the second through hole 115 to achieve the electrical connection between the first cathode electrode 114 and the second cathode electrode 214. For example, the conductive material may be metal or metal oxide, or the like, which is not limited herein. It is understood that the first cathode electrode 114 and the second cathode electrode 214 may alternatively be electrically connected to each other at sides of the first light emitting substrate 1 and the second light emitting substrate 2 through wires (not shown in the drawings).

As shown in FIGS. 1 to 6, the first light emitting substrate 1 and the second light emitting substrate 2 of the display panel 100 in the present disclosure may also include an encapsulation layer 40. For example, the encapsulation layer 40 may be arranged on a side of the second cathode electrode 214 away from the insulating layer 215 and may cover the second cathode electrode 214, the insulating layer 215, and so on.

Further, when the first light emitting substrate 1 and the second light emitting substrate 2 are stacked, connection between the first conductive portion 104 and the second anode extension portion 2112 may be as follows. A first connection portion 14 may be arranged at an end of the first conductive portion 104 away from the first anode electrode 111. A via-hole conduction portion 24 may be arranged at a side of the second anode extension portion 2112 near the first substrate 10 to lead the second anode extension portion 2112 to an exterior of the encapsulation layer 40. A second connection portion 25 may be arranged at a position of the via-hole conduction portion 24 away from the encapsulation layer 40. Furthermore, the first connection portion 14 and the second connection portion 25 may be connected to each other to achieve connection and conduction between the first conductive portion 104 and the second anode extension portion 2112.

For example, each of the first connection portion 14 and the second connection portion 25 may be a soldering pad. The via-hole conduction portion 24 may be formed by defining a hole in the encapsulation layer 40 and the insulating layer 215 and filling or electroplating a conductive material in the hole. The first connection portion 14 and the second connection portion 25 may be connected to each other by soldering or adhering via a conductive adhesive or the like to achieve electrical connection between the first conductive portion 104 to the second anode extension portion 2112 and achieve fixation between the first light emitting substrate 1 and the second light emitting substrate 2. Similarly, the second cathode electrode 214 and the second conductive portion 116 may be electrically connected to each other in a same manner. That is, connection portions (such as a soldering pad) may be respectively arranged at positions of the second cathode electrode 214 and the second conductive portion 116 corresponding to each other, and the connection portions at the corresponding positions may be soldered or adhered to each other, such that connection and conduction between the second cathode electrode 214 and the second conductive portion 116 may be achieved.

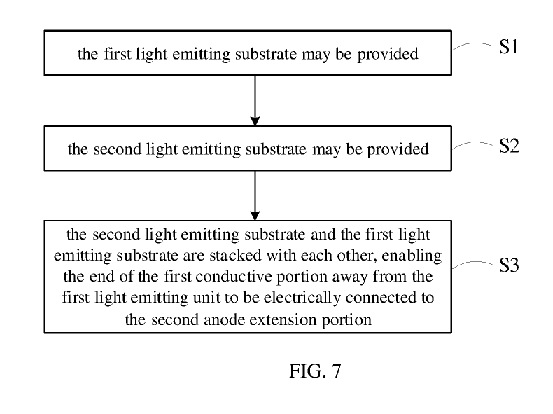

As shown in FIG. 7, FIG. 7 is a flow chart of a method of manufacturing the display panel according to an embodiment of the present disclosure.

In order to solve the above problem, the present disclosure further provides a method of manufacturing the display panel 100, and the method may include following operations.

In an operation S1, the first light emitting substrate may be provided.

Specifically, as shown in FIGS. 1 to 7, the first light emitting substrate 1 may include: the first substrate 10 and the plurality of first light emitting units 11. The first substrate 10 may have the first surface 101, the second surface 102 opposite to the first surface 101, and the plurality of first through holes 103 extending from the first surface 101 to the second surface 102. The first conductive portion 104 may be received in each of the plurality of first through holes 103. The plurality of first light emitting units 11 may be arranged on a side of the first surface 101 of the first substrate 10. Each of the plurality of first light emitting units 11 may include the first anode electrode 111, the first pixel definition layer 112, the first organic light emitting layer 113, and the first cathode electrode 114. A specific structure of the first light emitting substrate 1 may be referred to the above description, and will not be repeated herein.

It can be understood that in the operation S1, according to structures corresponding to the three embodiments of the display panel 100 described above, an order of preparing the first anode extension portion 1112 and the first pixel definition layer 112 on the first light emitting substrate 1 may be adjusted accordingly. For example, corresponding to the structure of the display panel 100 in the first embodiment, the first anode extension portion 1112 may be disposed between the first pixel definition layer 112 and the first substrate 10. The first anode extension portion 1112 may be prepared firstly, and the first pixel definition layer 112 may be prepared subsequently. Corresponding to the structure of the display panel 100 in the third embodiment, the first anode extension portion 1112 may extend from a side of the first anode conductive layer 1111 to the surface of the first pixel definition layer 112 away from the first substrate 10. Therefore, the first pixel definition layer 112 may be prepared firstly, and the first anode extension portion 1112 may be prepared subsequently.

In addition, corresponding to the structure of the display panel 100 in the third embodiment, each first through hole 103 may penetrate the first pixel definition layer 112. When depositing the first pixel definition layer 112, the position where the plurality of first through hole 103 penetrates the first pixel definition layer 112 may be reserved. Alternatively, after depositing the first pixel definition layer 112 is completed, a hole may be formed in the first pixel definition layer 112 at the position corresponding to the first through hole 103, and the hole may be communicated to the first through hole 103.

In an operation S2, the second light emitting substrate may be provided.

Specifically, as shown in FIGS. 1 to 7, the second light emitting substrate 2 may include: the second substrate 20 and the plurality of second light emitting units 21. The second substrate 20 may have the third surface 201 and the fourth surface 202 opposite to the third surface 201. The plurality of second light emitting units 21 may be arranged on a side of the third surface 201 of the second substrate 20. Each of the plurality of second light emitting units 21 may include the second anode electrode 211, the second pixel definition layer 212, the second organic light emitting layer 213, and the second cathode electrode 214. The second pixel definition layer 212 may define the second opening 2121. The second anode electrode 211 may include the second anode conductive layer 2111 received in the second opening 2121 and the second anode extension portion 2111 extending from a side of the second anode conductive layer 2111 to the surface of the second pixel definition layer 212 away from the second substrate 20. A specific structure of the second light emitting substrate 2 may be referred to the above description, and will not be repeated herein.

In an operation S3, the second light emitting substrate and the first light emitting substrate are stacked with each other, enabling the end of the first conductive portion away from the first light emitting unit to be electrically connected to the second anode extension portion.

Specifically, after the second light emitting substrate 2 is stacked with the first light emitting substrate 1, the second light emitting substrate 2 and the first light emitting substrate 1 may be secured at a periphery thereof y the frame adhesive or the bonding layer 30 (such as glue). In this way, the end of the first conductive portion 104 away from the first light emitting unit 11 may be electrically connected to the second anode extension portion 2112, and the other end of the first conductive portion 104 may be electrically connected to the first cathode electrode 114 or the first cathode extension portion. Furthermore, the connection 23 at which the first conductive portion 104 and the second anode extension portion 2112 are electrically connected to each other may be further secured by bonding or soldering. Subsequently, power supply and conduction may be achieved by the drive circuit. In this way, functions of the tandem OLEDs may be achieved. Stability of connection between the second light emitting substrate 2 and the first light emitting substrate 1 may be ensured, and overall circuit performance may be optimized.

According to the present disclosure, the display panel may include: the first light emitting substrate and the second light emitting substrate stacked with the first light emitting substrate. The first light emitting substrate includes the first substrate and the plurality of first light emitting units. The first substrate has the first surface, the second surface opposite to the first surface, and the first through holes that extend from the first surface to the second surface. The first conductive portion is received in each first through hole. The plurality of first light emitting units are arranged on the side of the first substrate. Each of the plurality of first light emitting units includes the first anode electrode, the first pixel definition layer, the first organic light emitting layer, and the first cathode electrode. The second light emitting substrate includes the second substrate and the plurality of second light emitting units. The second substrate has the third surface and the fourth surface opposite to the third surface. The plurality of second light emitting units are arranged on the side of the third surface of the second substrate. Each of the plurality of second light emitting units includes the second anode electrode, the second pixel definition layer, the second organic light emitting layer, and the second cathode electrode. The second pixel definition layer has the second opening. The second anode electrode includes the second anode conductive layer received in the second opening and the second anode extension portion that extends from the side of the second anode conductive layer to the surface of the second pixel definition layer away from the second substrate. The end of the first conductive portion away from the first light emitting unit is electrically connected to the second anode extension portion. The first light emitting substrate further includes the drive circuit layer. The drive circuit layer includes the drive circuit. The first anode electrode is electrically connected to the drive circuit. The other end of the first conductive portion is electrically connected to the drive circuit or electrically connected to the first anode electrode. Alternatively, the second light emitting substrate further includes the drive circuit layer, the drive circuit layer includes the drive circuit. The drive circuit is electrically connected to the second anode electrode. In the present disclosure, the second anode extension portion is arranged on the second light emitting substrate that is stacked with the first light emitting substrate, and the through hole is defined in the first light emitting substrate to form the first conductive portion and the second anode extension portion. Furthermore, the first conductive portion, which is formed based on TGB, is accurately in contact with and electrically connected to the anode electrode of the first light emitting substrate. In this way, the first light emitting substrate and the second light emitting substrate are conductive to each other. A simple process is provided, each light emitting substrate that is to be stacked on another light emitting substrate can be individually prepared, and a plurality of light emitting substrates may be electrically connected to each other through the through hole. In this way, a high preparation efficiency may be achieved, the product yield may be increased, and manufacturing costs of the display panel may be reduced.

The tandem OLED component of the display panel 100 in the present disclosure has following advantages. Firstly, stacking of OLEDs may be achieved based on the TGV, such that functions of tandem OLED components may be achieved. Secondly, a layout space occupied for the TGV is significantly small, such that opening requirements of high-resolution displays may be met. Thirdly, in the related art, the FMM may be applied to obtain the tandem OLEDs, which may require a large redundant space to be left for process deviations occurring in a process of FMM evaporation. However, in the present disclosure, TGV is performed after OLEDs are stacked. In this way, as long as stacking and splicing precision (such as coaxial arrangement of the first opening 1121 and the second opening 2121) can be controlled, a plurality of layers of organic light emitting materials may not affect each other, such that the light-emitting effect may be ensured. Furthermore, connection based on TGV may have a simple preparation process and generate a high product yield.

The above is only an implementation of the present disclosure, and is not intended to limit the scope of the present disclosure. Any equivalent structure or equivalent process transformation performed based on the contents of the specification and the accompanying drawings of the present disclosure, applied directly or indirectly in other related technical fields, shall be equivalently included in the scope of the present disclosure.

What is claimed is:

1. A display panel, comprising: a first light emitting substrate and a second light emitting substrate stacked with the first light emitting substrate; wherein,
the first light emitting substrate comprises:
a first substrate, having a first surface, a second surface opposite to the first surface, and a plurality of first through holes extending from the first surface to the second surface, wherein a first conductive portion is received in each of the plurality of first through holes;
a plurality of first light emitting units, arranged on a side of the first surface of the first substrate, wherein each of the plurality of first light emitting units comprises a first anode electrode, a first pixel definition layer, a first organic light emitting layer and a first cathode electrode;
the second light emitting substrate comprises:
a second substrate, having a third surface and a fourth surface opposite to the third surface;
a plurality of second light emitting units, arranged on a side of the third surface of the second substrate, wherein each of plurality of second light emitting units comprises a second anode electrode, a second pixel definition layer, a second organic light emitting layer, and a second cathode electrode; the second pixel definition layer defines a second opening;
wherein, the second anode electrode comprises a second anode conductive layer received in the second opening and a second anode extension portion extending from a side of the second anode conductive layer to a surface of the second pixel definition layer away from the second substrate; and an end of the first conductive portion away from the plurality of first light emitting units is electrically connected to the second anode extension portion;
wherein, the first light emitting substrate further comprises a drive circuit layer, the drive circuit layer comprises a drive circuit; the first anode electrode is electrically connected to the drive circuit; the other end of the first conductive portion is electrically connected to the drive circuit or the first anode electrode; and/or
the second light emitting substrate further comprises a drive circuit layer, the drive circuit layer comprises a drive circuit, the drive circuit is electrically connected to the second anode electrode.

2. The display panel according to claim 1, wherein,
the first pixel definition layer defines a first opening; the first anode electrode comprises a first anode conductive layer received in the first opening and a first anode extension portion; the first anode extension portion extends from a side of the first anode conductive layer to a position between the first pixel definition layer and the first substrate; the other end of the first conductive portion is electrically connected to the first anode extension portion.

3. The display panel according to claim 2, wherein, the first opening and the second opening are coaxially arranged to each other; the first through hole is staggered with the first opening.

4. The display panel according to claim 1, wherein,
the first light emitting substrate comprises a first drive circuit layer, the first drive circuit layer comprises a first drive circuit; the first light emitting substrate further comprises:
a conductive interconnection layer, disposed between the first substrate and the first drive circuit layer and electrically connected to the first drive circuit;
wherein the other end of the first conductive portion is electrically connected to the conductive interconnection layer.

5. The display panel according to claim 1, wherein,
the first pixel definition layer has a first opening; the first anode electrode comprises a first anode conductive layer received in the first opening and a first anode extension portion; the first anode extension portion extends from a side of the first anode conductive layer to a surface of the first pixel definition layer away from the first substrate; each of the plurality of first through holes penetrates the first pixel definition layer; the other end of the first conductive portion extends through the first pixel definition layer and is electrically connected to the first anode extension portion.

6. The display panel according to claim 5, wherein, the first opening and the second opening are coaxially arranged to each other; the first through hole is staggered with the first opening.

7. The display panel according to claim 1, wherein,
each of the plurality of first through holes is a straight through hole perpendicular to the first substrate.

8. The display panel according to claim 1, wherein,
each of the plurality of first through holes is a straight through hole that is inclined with respect to a thickness direction of the first substrate.

9. The display panel according to claim 1, wherein, each of the plurality of first through holes comprises a first hole section and a second hole section communicated to the first hole section;
one of the first hole section and the second hole section extends along a thickness direction of the first substrate; and the other one of the first hole section and the second hole section extends inclinedly relative to the thickness direction of the first substrate.

10. The display panel according to claim 1, wherein,
the first substrate further has a plurality of second through holes extending from the first surface to the second surface; a second conductive portion is received in each of the plurality of second through holes; one end of the second conductive portion is electrically connected to the first cathode electrode; and the other end of the second conductive portion is electrically connected to the second cathode electrode.

11. The display panel according to claim 1, wherein, the first substrate is a glass substrate; the first anode electrode is a light transmissive conductive layer.

12. The display panel according to claim 1, wherein, the drive circuit layer is arranged in only the first light emitting substrate;
a frame adhesive or a bonding layer is disposed between the second surface of the first substrate and the third surface of the second substrate.

13. The display panel according to claim 1, wherein, each of the plurality of second light emitting units further comprises an insulating layer; the insulating layer is disposed on a side of the second pixel definition layer and the second organic light emitting layer away from the second substrate and covers the second anode electrode, the second pixel definition layer, and a portion of the second organic light emitting layer.

14. The display panel according to claim 1, wherein a connection at which the first conductive portion and the second anode extension are electrically connected to each other is secured by bonding or soldering.

15. The display panel according to claim 2, wherein the first anode extension portion of the first organic light emitting layer of one of the plurality of light emitting units is spaced apart from the first organic light emitting layer of another one of the plurality of light emitting units adjacent to the one of the plurality of light emitting units.

16. The display panel according to claim 1, wherein the first light emitting substrate and the second light emitting substrate are further arranged with an encapsulation layer.

17. The display panel according to claim 16, wherein a first connection portion is arranged at the end of the first conductive portion away from the first anode electrode; a via-hole conduction portion is arranged at a side of the second anode extension portion near the first substrate to lead the second anode extension portion to an exterior of the encapsulation layer; a second connection portion is arranged at a side of the via-hole conduction portion away from the encapsulation layer; and the first connection portion and the second connection portion are connected to each other.

18. The display panel according to claim 17, wherein each of the first connection portion and the second connection portion is a soldering pad.

19. A method of manufacturing a display panel, comprising:
providing a first light emitting substrate; wherein the first light emitting substrate comprises:
a first substrate, having a first surface, a second surface opposite to the first surface, and a plurality of first through holes extending from the first surface to the second surface, wherein a first conductive portion is received in each of the plurality of first through holes;
a plurality of first light emitting units, arranged on a side of the first surface of the first substrate, wherein each of the plurality of first light emitting units comprises a first anode electrode, a first pixel definition layer, a first organic light emitting layer and a first cathode electrode;
providing a second light emitting substrate; wherein the second light emitting substrate comprises:
a second substrate, having a third surface and a fourth surface opposite to the third surface;
a plurality of second light emitting units, arranged on a side of the third surface of the second substrate; wherein each of the plurality of second light emitting units comprises a second anode electrode, a second pixel definition layer, a second organic light emitting layer, and a second cathode electrode; the second pixel definition layer has a second opening; wherein the second anode electrode comprises a second anode conductive layer received in the second opening and a second anode extension portion extending from a side of the second anode conductive layer to a surface of the second pixel definition layer away from the second substrate;
stacking the second light emitting substrate and the first light emitting substrate, enabling one end of the first conductive portion away from the first light emitting unit to be electrically connected to the second anode extension portion.

20. The method according to claim 19, wherein the first pixel definition layer defines a first opening; the first anode electrode comprises a first anode conductive layer received in the first opening and a first anode extension portion; the first anode extension portion extends from a side of the first anode conductive layer to a position between the first pixel definition layer and the first substrate; the other end of the first conductive portion is electrically connected to the first anode extension portion.
